(19) United States
(12) Patent Application Publication
(10) Pub. No.: US 2024/0079269 A1
(43) Pub. Date: Mar. 7, 2024

(54) PLATING METHOD AND PLATING APPARATUS

(71) Applicant: Tokyo Electron Limited, Tokyo (JP)

(72) Inventor: Tomonori Esaki, Kikuchi-gun, Kumamoto (JP)

(21) Appl. No.: 18/261,157

(22) PCT Filed: Jan. 6, 2022
(86) PCT No.: PCT/JP2022/000191

§ 371 Date: Jul. 12, 2023

(30) Foreign Application Priority Data
Jan. 18, 2021 (JP) 2021-005548

(51) Int. Cl. H01L 21/768; C23C 18/34

(52) U.S. Cl. CPC H01L 21/76874; C23C 18/34; H01L 21/76877

(57) ABSTRACT

A plating method includes preparing; generating a plating liquid; and performing an electroless plating processing. In the preparing, a substrate is prepared. In the generating of the plating liquid, the plating liquid M is generated by mixing a first chemical liquid L1 containing a metal ion, a reducing agent and a complexing agent with a second chemical liquid L2 containing a pH adjuster as a main component. In the performing of the electroless plating processing, the electroless plating processing is performed on the substrate by using the generated plating liquid M immediately after the generating of the plating liquid.

### TECHNICAL FIELD

The various aspects and embodiments described herein pertain generally to a plating method and a plating apparatus.

### BACKGROUND

Conventionally, as a way to form a multi-layer wiring on a semiconductor wafer (hereinafter, simply referred to as a wafer) as a substrate, there is known a method of performing an electroless plating processing by using a metal wiring exposed at a bottom surface of a via as a catalyst to thereby fill an inside of the via with a metal (see Patent Document 1).

### PRIOR ART DOCUMENT

Patent Document 1: International Publication No. 2019/163531

### DISCLOSURE OF THE INVENTION

### Problems to be Solved by the Invention

Exemplary embodiments provide a technique capable of suppressing deterioration of a plating liquid used in an electroless plating processing.

### Means for Solving the Problems

In an exemplary embodiment, a plating method includes preparing; generating a plating liquid; and performing an electroless plating processing. In the preparing, a substrate is prepared. In the generating of the plating liquid, the plating liquid is generated by mixing a first chemical liquid containing a metal ion, a reducing agent and a complexing agent with a second chemical liquid containing a pH adjuster as a main component. In the performing of the electroless plating processing, the electroless plating processing is performed on the substrate by using the generated plating liquid immediately after the generating of the plating liquid.

### Effect of the Invention

According to the exemplary embodiment, it is possible to suppress the deterioration of the plating liquid used in the electroless plating processing.

### BRIEF DESCRIPTION OF THE DRAWINGS

FIG. 1 is a schematic plan view illustrating a configuration of a substrate processing system according to an exemplary embodiment.

FIG. 2 is a schematic cross-sectional view illustrating a configuration of a plating unit according to the exemplary embodiment.

FIG. 3 is a schematic cross-sectional view illustrating a configuration of a heat treatment unit according to the exemplary embodiment.

FIG. 4 is an enlarged cross-sectional view illustrating a surface state of a wafer before being subjected to a plating processing according to the exemplary embodiment.

FIG. 5 is a diagram for describing a plating method according to the exemplary embodiment.

FIG. 6 is an enlarged cross-sectional view illustrating the surface state of the wafer after being subjected to the plating processing according to the exemplary embodiment.

FIG. 7 is a diagram for describing a plating method according to a first modification example of the exemplary embodiment.

FIG. 8 is a diagram for describing the plating method according to the first modification example of the exemplary embodiment.

FIG. 9 is a diagram for describing a plating method according to a second modification example of the exemplary embodiment.

FIG. 10 is a flowchart illustrating a processing sequence of the plating processing according to the exemplary embodiment.

FIG. 11 is a flowchart illustrating another processing sequence of the plating processing according to the exemplary embodiment.

### DETAILED DESCRIPTION

Hereinafter, exemplary embodiments of a plating method and a plating apparatus of the present disclosure will be described in detail with reference to the accompanying drawings. The present disclosure is not limited to the exemplary embodiments to be described below. Further, it should be noted that the drawings are schematic and relations in sizes of individual components and ratios of the individual components may sometimes be different from actual values. Even between the drawings, there may exist parts having different dimensional relationships or different ratios.

Conventionally, as a way to form a multi-layer wiring on a semiconductor wafer (hereinafter, simply referred to as a wafer) as a substrate, there is known a method of performing an electroless plating processing by using a metal wiring exposed at a bottom surface of a via as a catalyst to thereby fill an inside of a via with a metal.

Further, with the recent trend of miniaturization of the multi-layer wiring, the area of the metal wiring exposed at the bottom surface of the via is gradually decreasing. In order to fill the inside of the via through the electroless plating processing, it is required to increase the activity of the plating liquid.

Meanwhile, if the activity of the plating liquid is increased, a reaction between a metal ion and a reducing agent proceeds in the stored plating liquid even in the atmosphere, which raises a risk that the plating liquid may be deteriorated before the electroless plating processing is performed.

In this regard, there is a demand for a technique capable of overcoming the aforementioned problem and suppressing the deterioration of the plating liquid used in the electroless plating processing.

### Outline of Substrate Processing System

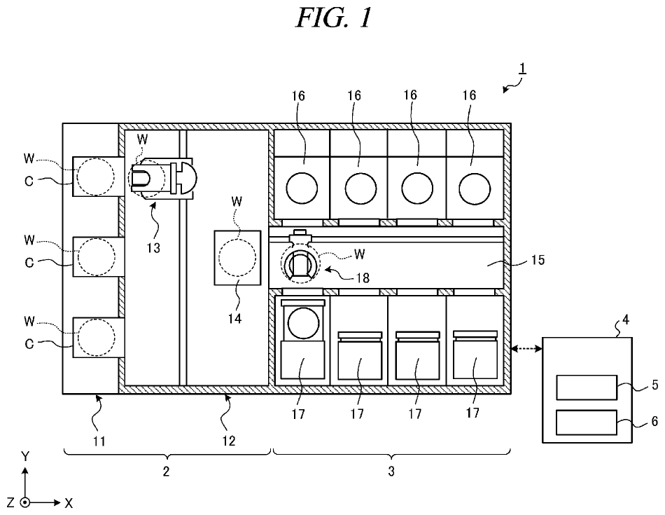

First, a schematic configuration of a substrate processing system 1 according to an exemplary embodiment will be explained with reference to FIG. 1. FIG. 1 is a schematic plan view illustrating the configuration of the substrate processing system 1 according to the exemplary embodiment.

In the following description, to clarity positional relationship, the X-axis, the Y-axis and the Z-axis which are orthogonal to each other will be defined, and the positive Z-axis direction will be regarded as a vertically upward direction.

As depicted in FIG. 1, the substrate processing system 1 includes a carry-in/out station 2 and a processing station 3. The carry-in/out station 2 and the processing station 3 are provided adjacent to each other.

The carry-in/out station 2 is provided with a carrier placing section 11 and a transfer section 12. In the carrier placing section 11, a plurality of carriers C is placed to accommodate a plurality of semiconductor wafers W (hereinafter, referred to as “wafers W”) horizontally. The wafer W is an example of a substrate.

The transfer section 12 is provided adjacent to the carrier placing section 11, and provided with a substrate transfer device 13 and a delivery unit 14 therein. The substrate transfer device 13 is provided with a wafer holding mechanism configured to hold the wafer W. Further, the substrate transfer device 13 is movable horizontally and vertically and pivotable around a vertical axis, and is configured to transfer the wafers W between the carriers C and the delivery unit 14 by using the wafer holding mechanism.

The processing station 3 is provided adjacent to the transfer section 12. The processing station 3 is provided with a transfer section 15, a plurality of plating units 16, and a plurality of heat treatment units 17.

The plating units 17 and the heat treatment units 17 are arranged at both sides of the transfer section 15. Further, the layout and the number of the plating units 16 and the heat treatment units 17 shown in FIG. 1 are just an example, and are not limited to those shown in FIG. 1.

The transfer section 15 is provided with a substrate transfer device 18 therein. The substrate transfer device 18 is provided with a wafer holding mechanism configured to hold the wafer W. Further, the substrate transfer device 18 is movable horizontally and vertically and pivotable around a vertical axis. The substrate transfer device 18 is configured to transfer the wafers W between the delivery unit 14, the plating units 16, and the heat treatment units 17 by using the wafer holding mechanism.

The plating unit 16 is configured to perform a predetermined electroless plating processing on the wafer W transferred by the substrate transfer device 18. A configuration example of this plating unit 16 will be elaborated later.

The heat treatment unit 17 is configured to perform a predetermined heat treatment on the wafer W transferred by the substrate transfer device 18. A configuration example of this heat treatment unit 17 will be elaborated later.

Further, the substrate processing system 1 is provided with a control device 4. The control device 4 is, for example, a computer, and includes a controller 5 and a storage 6.

The controller 5 includes a microcomputer having a CPU (Central Processing Unit), a ROM (Read Only Memory), a RAM (Random Access Memory), an input/output port, and so forth as well as various kinds of circuits.

The CPU of this microcomputer implements a control over the transfer sections 12 and 15, the plating unit 16, the heat treatment unit 17, and so forth by reading out and executing a program stored in the ROM.

Further, the program may have been recorded on a computer-readable recording medium, and may be installed from the recording medium to the storage 6 of the control device 4. The computer-readable recording medium may be, by way of non-limiting example, a hard disk HD, a flexible disk FD, a compact disk CD, a magnetic optical disk MO, a memory card, or the like.

The storage 6 may be implemented by, for example, semiconductor memory device such as RAM or a flash memory, or a storage device such as a hard disk or an optical disk.

In the substrate processing system 1 configured as described above, the substrate transfer device 13 of the carry-in/out station 2 first takes out the wafer W from the carrier C placed in the carrier placing section 11, and then places the taken wafer W on the delivery unit 14. The wafer W placed on the delivery unit 14 is taken out from the delivery unit 14 by the substrate transfer device 18 of the processing station 3 and carried into the plating unit 16.

The wafer W carried into the plating unit 16 is subjected to the predetermined electroless plating processing by the plating unit 16, and is then carried out from the plating unit 16 and carried into the heat treatment unit 17 by the substrate transfer device 18.

The wafer W carried into the heat treatment unit 17 is subjected to the predetermined heat treatment by the heat treatment unit 17, and is then carried out from the heat treatment unit 17 by the substrate transfer device 18 and placed on the delivery unit 14. Then, the wafer W placed on the delivery unit 14 after being subjected to all the required processings is returned back into the carrier C of the carrier placing section 11 by the substrate transfer device 13.

### Outline of Plating Unit

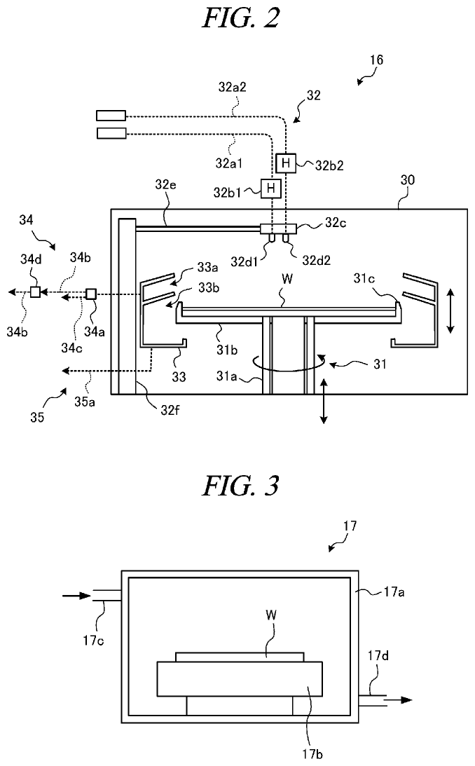

Now, a schematic configuration of the plating unit 16 will be explained with reference to FIG. 2. FIG. 2 is a schematic cross-sectional view illustrating the configuration of the plating unit 16 according to the exemplary embodiment. The plating unit 16 is configured as, for example, a single-wafer type processing unit configured to process the wafers W one by one.

The plating unit 16 is equipped with, as illustrated in FIG. 2, a housing 30, a substrate holder 31, a chemical liquid supply 32, a cup 33, and liquid draining units 34 and 35.

The substrate holder 31 is configured to hold and rotate the wafer W within the housing 30. The substrate holder 31 has a rotation shaft 31a, a turntable 31b, a wafer chuck 31c, and a non-illustrated rotating mechanism.

The rotation shaft 31a has a hollow cylindrical shape and extends vertically within the housing 30. The turntable 31b is mounted to an upper end of the rotation shaft 31a. The wafer chuck 31c is provided at a peripheral portion of a top surface of the turntable 31b to support the wafer W.

The substrate holder 31 is controlled by the controller 5 of the control device 4, and the rotation shaft 31a is rotated by the rotating mechanism. As a result, the wafer W supported by the wafer chuck 31c can be rotated.

The chemical liquid supply 32 is configured to supply a preset chemical liquid to a surface of the wafer W held by the substrate holder 31. The chemical liquid supply 32 includes a first supply 32a1 configured to supply a first chemical liquid L1 (see FIG. 5) to the surface of the wafer W; and a second supply 32a2 configured to supply a second chemical liquid L2 (see FIG. 5) to the surface of the wafer W.

The first chemical liquid L1 according to the exemplary embodiment contains a metal ion, a reducing agent, and a complexing agent. The metal ion contained in the first chemical liquid L1 may be, by way of example, a cobalt (Co) ion, a nickel (Ni) ion, a tungsten (W) ion, a copper (Cu) ion, a palladium (Pd) ion, a gold (Au) ion, or the like.

The reducing agent contained in the first chemical liquid L1 is, for example, hydrazine, glyoxylic acid, EDTA (ethylene diamine tetraacetic acid), dimethylamine borane, or the like. The complexing agent contained in the first chemical liquid L1 may be one capable of forming a complex with the metal ion, for example, citric acid or sodium citrate when the metal ion is a cobalt ion.

The second chemical liquid L2 according to the exemplary embodiment is a chemical liquid containing a pH adjuster as a main component. In addition, in the present disclosure, “containing the pH adjuster as the main component” means containing the pH adjuster in an amount of 80 (vol %) or more.

The pH adjuster according to the exemplary embodiment is a chemical liquid configured to adjust a pH of the first chemical liquid L1 such that it is increased. For example, the pH adjuster may be a high-alkaline aqueous solution such as TMAH (Tetra Methyl Ammonium Hydroxide) or sodium hydroxide.

The first supply 32a1 is provided with a heater 32b1 configured to increase the temperature of the first chemical liquid L1 to be supplied to the wafer W to a predetermined temperature, and the second supply 32a2 is provided with a heater 32b2 configured to increase the temperature of the second chemical liquid L2 to be supplied to the wafer W to a preset temperature.

Further, the chemical liquid supply 32 has a nozzle head 32c, and a first nozzle 32d1 and a second nozzle 32d2 are mounted to the nozzle head 32c. The first nozzle 32d1 is a nozzle corresponding to the first supply 32a1, and the second nozzle 32d2 is a nozzle corresponding to the second supply 32a2.

The nozzle head 32c is provided to a leading end of an arm 32e. This arm 32e is movable up and down, and is fixed to a support shaft 32f configured to be rotated by a non-illustrated rotating mechanism (not shown) so as to be rotatable.

With this configuration, the chemical liquid supply 32 is capable of discharging the first chemical liquid L1 and the second chemical liquid L2 from a required height to a target position on the surface of the wafer W through the first nozzle 32d1 and the second nozzle 32d2, respectively.

In addition, although not shown in FIG. 2, the chemical liquid supply 32 may be additionally equipped with a cleaning liquid supply configured to supply a preset cleaning liquid to the wafer W.

The cup 33 receives the processing liquid scattered from the wafer W. The cup 33 has two drain ports 33a and 33b, and is configured to be movable up and down by a non-illustrated elevating mechanism. The two drain ports 33a and 33b are connected to the liquid draining units 34 and 35, respectively.

The liquid draining units 34 and 35 are configured to drain the processing liquid collected in the drain ports 33a and 33b, respectively. The liquid draining unit 34 has a recovery path 34b and a waste path 34c which are switched by a path switching device 34a. The recovery path 34b is, for example, a path through which the processing liquid is collected to reuse it, and the waste path 34c is a path through which the processing liquid is drained out.

Further, a cooling buffer 34d configured to cool the plaiting liquid M when the chemical liquid to be recovered is the plating liquid M (see FIG. 5) is provided on an outlet side of the recovery path 34b. In addition, the liquid draining unit 35 only has a waste path 35a.

### Outline of Heat Treatment Unit

Now, a schematic configuration of the heat treatment unit 17 will be explained with reference to FIG. 3. FIG. 3 is a schematic cross-sectional view illustrating the configuration of the heat treatment unit 17 according to the exemplary embodiment. The heat treatment unit 17 is configured as, for example, a single-wafer type processing unit configured to process the wafers W one by one.

As depicted in FIG. 3, the heat treatment unit 17 includes a hermetically sealable housing 17a and a hot plate 17b disposed inside the housing 17a. Further, the housing 17a is provided with a transfer opening (not shown) through which the wafer W is carried in and out; a gas supply port 17c through which a preset atmosphere gas is supplied into the housing 17a; and a gas exhaust port 17d through which the atmosphere gas is exhausted from the inside of the housing 17a.

The wafer W is carried in through the transfer opening to be placed on the hot plate 17b. Then, by increasing the temperature of the hot plate 17b to a predetermined temperature while supplying an atmosphere gas corresponding to each heat treatment, the predetermined heat treatment can be performed on the wafer W.

### Exemplary Embodiment

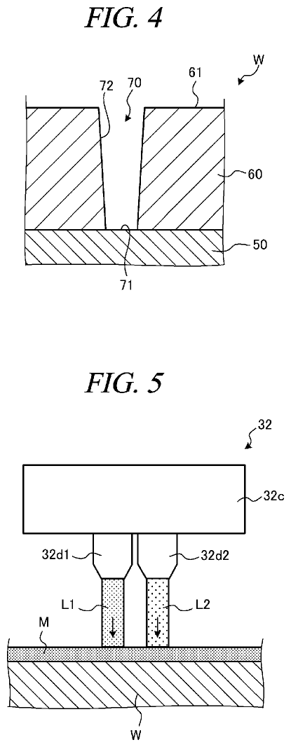

Now, details of a plating processing according to the exemplary embodiment will be explained with reference to FIG. 4 to FIG. 6. FIG. 4 is an enlarged cross-sectional view illustrating a surface state of the wafer W before being subjected to the plating processing according to the exemplary embodiment.

Further, the wafer W shown in FIG. 4 is provided with a non-illustrated device already formed thereon. Below, various kinds of processings of filling a via 70, which is formed in an insulating film 60 on a wiring 50, with a metal wiring in a wiring forming process after the formation of the device (so-called BEOL (Back End of Line)) will be explained.

As shown in FIG. 4, the wiring 50 made of a metal is formed on the wafer W, and the insulating film 60 is formed on this wiring 50. In the present exemplary embodiment, the entire insulating film 60 is made of an oxide film.

The wiring 50 according to the exemplary embodiment is made of an element that does not diffuse into the insulating film 60 which is the oxide film. By way of non-limiting example, the wiring 50 is made of a conductive material including Co, Ni or Ru.

Further, in the wafer W, the via 70 is formed at a preset position in the insulating film 60. This via 70 is formed to extend from a top surface 61 of the insulating film 60 to the wiring 50. The via 70 has a bottom surface 71 at which the wiring 50 is exposed; and a side surface 72.

Here, as a way to form the via 70 in the insulating film 60 of the wafer W, a conventionally known method may be appropriately employed. To be specific, a general-purpose technique using a fluorine-based gas, a chlorine-based gas, or the like may be employed as a dry etching technique, for example.

In particular, as a way to form the via 70 having a high aspect ratio (a ratio of a depth to a diameter), an ICP-RIE (Inductively Coupled Plasma Reactive Ion Etching) technique enabling a high-speed deep etching may be adopted.

By way of example, a so-called Bosch process in which an etching process using sulfur hexafluoride (SF₆) and a protection process using a C₄F₈ gas or the like are repeatedly performed may be appropriately adopted.

As illustrated in FIG. 4, the wafer W having the via 70 formed in the insulating film 60 on the wiring 50 is carried into the above-described plating unit 16 to be subjected to the predetermined electroless plating processing.

FIG. 5 is a diagram for describing a plating method according to the exemplary embodiment. As shown in FIG. 5, in the plating method according to the exemplary embodiment, the controller 5 (see FIG. 1) controls the chemical liquid supply 32 to discharge the first chemical liquid L1 from the first nozzle 32d1 and the second chemical liquid L2 from the second nozzle 32d2 onto the surface of the wafer W.

Accordingly, the controller 5 allows the first chemical liquid L1 and the second chemical liquid L2 to be mixed on the surface of the wafer W to generate the plating liquid M. Then, immediately after the plating liquid M is generated, the controller 5 performs the electroless plating processing on the via 70 (see FIG. 4) by using the plating liquid M.

In the present disclosure, “immediately after the plating liquid M is generated” means a period until deterioration of the plating liquid M progresses after the plating liquid M is generated.

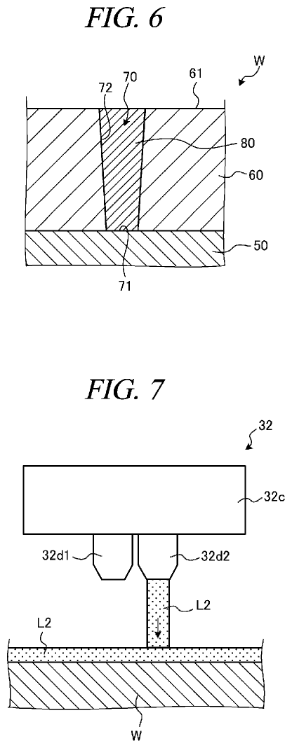

Through this electroless plating processing, an electroless plating film 80 is formed from the bottom surface 71 of the via 70 in a bottom-up manner by using, as the catalyst, the wiring 50 exposed at the bottom surface 71 of the via 70, and the inside of the via 70 is filled with the electroless plating film 80, as illustrated in FIG. 6. FIG. 6 is an enlarged cross-sectional view illustrating the surface state of the wafer W after being subjected to the plating processing according to the exemplary embodiment.

In this way, in the present exemplary embodiment, the electroless plating film 80 is formed from the bottom surface 71 in the bottom-up manner by using, as the catalyst, the wiring 50 exposed at the bottom surface 71, and the inside of the via 70 is filled with the electroless plating film 80. Accordingly, it is possible to form the metal wiring without having the void or the seam inside the via 70 in which the metal wiring is difficult to form due to the high aspect ratio.

Here, in the exemplary embodiment, since the first chemical liquid L1, which is the source material of the plating liquid M, does not contain the pH adjuster, the first chemical liquid L1 is set to have a pH at which the reaction between the metal ion and the reducing agent is suppressed (that is, to have low activity). The first chemical liquid L1 according to the exemplary embodiment has a pH ranging from, e.g., about 11 to 12.

In the exemplary embodiment, by mixing the second chemical liquid L2 containing the pH adjuster as the main component with the first chemical liquid L1, the pH of the first chemical liquid L1 is adjusted to be increased. As a result, in the plating liquid M generated by mixing the first chemical liquid L1 and the second chemical liquid L2, the reaction between the metal ion and the reducing agent is accelerated.

In this way, in the exemplary embodiment, it is possible to suppress the reaction between the metal ion and the reducing agent from proceeding even in the atmosphere in the stored first chemical liquid L1. Further, during the plating processing on the wafer W, the activity of the plating liquid M can be enhanced.

That is, in the exemplary embodiment, by mixing the first chemical liquid L1 and the second chemical liquid L2 to generate the plating liquid M immediately before the electroless plating processing, the deterioration of the plating liquid M used in the electroless plating processing can be suppressed.

Further, in the exemplary embodiment, the metal ion and the reducing agent are mixed in advance in the first chemical liquid L1. Accordingly, the activity of the generated plating liquid M can be increased as compared to a case where the plating liquid M is generated by mixing the metal ion and the reducing agent immediately before the electroless plating processing.

Therefore, according to the exemplary embodiment, even when the via 70 is miniaturized, the inside of the via 70 can be satisfactorily filled through the electroless plating processing.

In addition, the present disclosure is not limited to the case where the first liquid chemical L1 in which the metal ion and the reducing agent are mixed in advance is stored and used in the substrate processing system 1 or the like.

For example, in the present disclosure, in the first supply 32a1 (see FIG. 2) provided upstream of the first nozzle 32d1, the first chemical liquid L1 may be generated by mixing a third chemical liquid (not shown) containing the metal ion and a fourth chemical liquid (not shown) containing the reducing agent.

Accordingly, since the reaction between the metal ion and the reducing agent in the first chemical liquid L1 can be suppressed, the activity of the plating liquid M generated by using this first chemical liquid L1 can be increased.

Furthermore, in the exemplary embodiment, the pH of the first chemical liquid L1 may be increased by using the second chemical liquid L2 containing the high-alkaline aqueous solution as the main component. Thus, as compared to a case where the pH of the first chemical liquid L1 having a very high pH is reduced by using the second chemical liquid L2 containing an acidic aqueous solution as a main component, management of the first chemical liquid L1 may be eased.

Therefore, according to the exemplary embodiment, the electroless plating processing can be carried out in a simple manner.

Further, in the exemplary embodiment, the second chemical liquid L2 containing the pH adjuster as the main component only needs to be composed of the high-alkaline aqueous solution and inevitable impurities. Thus, management of the second liquid chemical L2 becomes easy, so that the electroless plating processing can be performed in a simple manner.

In addition, the present disclosure is not limited to the case where the second liquid chemical L2 is composed of the high-alkaline aqueous solution and the inevitable impurities. For example, a metal ion, a reducing agent, a complexing agent, or the like may be mixed in the high-alkaline aqueous solution as the main component.

Further, in the exemplary embodiment, the first chemical liquid L1 and the second chemical liquid L2 are simultaneously discharged to the wafer W from the first nozzle 32d1 and the second nozzle 32d2 to thereby generate the plating liquid M on the surface of the wafer W. Accordingly, the electroless plating processing on the wafer W can be performed immediately after the plating liquid M is generated.

Therefore, according to the exemplary embodiment, since the electroless plating processing can be performed before the plating liquid M deteriorates, the inside of the via 70 can be satisfactorily filled through the electroless plating processing even when the via 70 is miniaturized.

Furthermore, in the exemplary embodiment, the plating liquid M may be generated after increasing the temperature of at least one of the first chemical liquid L1 and the second chemical liquid L2 to a temperature (e.g., 40° C. to 70°) higher than a room temperature.

Therefore, since the electroless plating processing can be performed by using the plating liquid M whose temperature is higher than the room temperature, the inside of the via 70 can be more satisfactorily filled through the electroless plating processing even when the via 70 is miniaturized.

Upon the completion of the electroless plating processing described so far, the wafer W having the electroless plating film 80 formed thereon is then subjected to the preset cleaning processing in the plating unit 16. For example, this cleaning processing is performed by discharging the preset cleaning liquid onto the wafer W while spinning the wafer W. As a result, the plating liquid M or the like adhering to the surface of the wafer W is removed.

Then, the wafer W upon the completion of the cleaning processing is carried into the heat treatment unit 17 described above to be subjected to the predetermined heat treatment. For example, such heat treatment is performed by increasing the temperature of the wafer W to a preset temperature (e.g., 400° C.) by way of heating the hot plate 17b on which the wafer W is placed in a forming gas atmosphere containing a nitrogen gas and a hydrogen gas mixed at a certain ratio.

In this way, by performing the heat treatment on the electroless plating film 80, the electroless plating film 80 can be crystallized, so that electrical resistance of the metal wiring formed inside the via 70 can be reduced.

Through the various kinds of processings described so far, the inside of the via 70 having the high aspect ratio can be filled with the metal wiring successfully in the exemplary embodiment.

The above exemplary embodiment has been described for the example where the plating liquid M is generated by mixing the first chemical liquid L1 and the second chemical liquid L2 on the surface of the wafer W. However, the present disclosure is not limited thereto. By way of example, the plating liquid M may be generated by mixing the first chemical liquid L1 and the second chemical liquid L2 above the wafer W (that is, before the discharged first and second chemical liquids L1 and L2 reach the wafer W).

### First Modification Example

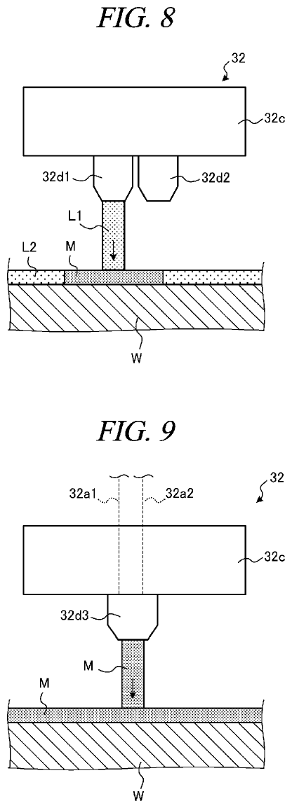

Now, various modification examples of the exemplary embodiment will be described with reference to FIG. 7 to FIG. 9. FIG. 7 and FIG. 8 are diagrams for describing a plating method according to a first modification example of the exemplary embodiment.

As shown in FIG. 7, in the first modification example, the controller 5 (see FIG. 1) controls the chemical liquid supply 32 to discharge the second chemical liquid L2 from the second nozzle 32d2. Accordingly, the controller 5 allows a liquid film of the second chemical liquid L2 to be formed on the surface of the wafer W.

Subsequently, as shown in FIG. 8, the controller 5 (see FIG. 1) controls the chemical liquid supply 32 to discharge the first chemical liquid L1 from the first nozzle 32d1. Accordingly, the controller 5 allows the discharged first chemical liquid L1 to be mixed with the liquid film of the second chemical liquid L2 on the surface of the wafer W to generate the plating liquid M.

Then, the controller 5 performs the electroless plating processing on the via 70 (see FIG. 4) by using the generated plating liquid M. Accordingly, the electroless plating film 80 (see FIG. 6) is formed inside the via 70.

In the first modification example described so far, the reaction between the metal ion and the reducing agent can be suppressed from progressing even in the atmosphere in the stored first chemical liquid L1, and, also, the activity of the plating liquid M can be increased in the plating processing on the wafer W, the same as in the above-described exemplary embodiment.

Thus, according to the first modification example, the deterioration of the plating liquid M used in the electroless plating processing can be suppressed.

Further, in the first modification example, since the electroless plating processing can be performed before the plating liquid M having the high activity deteriorates, the inside of the via 70 can be satisfactorily filled through the electroless plating processing even when the via 70 is miniaturized.

Moreover, although the first chemical liquid L1 is discharged to the wafer W on which the liquid film of the second chemical liquid L2 is formed in FIG. 7 and FIG. 8, the present disclosure is not limited thereto. For example, the second chemical liquid L2 may be discharged to the wafer W on which a liquid film of the first chemical liquid L1 is formed.

### Second Modification Example

FIG. 9 is a diagram for describing a plating method according to a second modification example of the exemplary embodiment. In the second modification example shown in FIG. 9, the configuration of the chemical liquid supply 32 is different from those of the exemplary embodiment and the first modification example described above.

Specifically, the chemical liquid supply 32 according to the second modification example has a mixing nozzle 32d3 instead of the first nozzle 32d1 and the second nozzle 32d2. This mixing nozzle 32d3 is connected to the first supply 32a1 configured to supply the first chemical liquid L1 (see FIG. 5) and the second supply 32a2 configured to supply the second chemical liquid L2 (see FIG. 5).

In this second modification example, the controller 5 (see FIG. 1) controls the chemical liquid supply 32 to mix the first chemical liquid L1 and the second chemical liquid L2 in the mixing nozzle 32d3 to generate the plating liquid M. Further, the controller 5 discharges the plating liquid M generated in the mixing nozzle 32d3 to the surface of the wafer W.

In this second modification example, the reaction between the metal ion and the reducing agent can be suppressed from proceeding even in the atmosphere in the stored first chemical liquid L1, and, also, the activity of the plating liquid M can be increased in the plating processing upon the wafer W, the same as in the above-described exemplary embodiment.

Thus, according to the second modification example, the deterioration of the plating liquid M used in the electroless plating processing can be suppressed.

Besides, in the second modification example, since the electroless plating processing can be performed before the plating liquid M having the high activity deteriorates, the inside of the via 70 can be satisfactorily filled through the electroless plating processing even when the via 70 is miniaturized.

A plating apparatus (substrate processing system 1) according to the exemplary embodiment includes the substrate holder 31 configured to hold the substrate (wafer W); the chemical liquid supply 32 configured to supply the chemical liquid to the substrate (wafer W); and the controller 5 configured to control the individual components. The controller 5 holds the substrate (wafer W) with the substrate holder 31. Further, the controller 5 controls the chemical liquid supply 32 to mix the first chemical liquid L1 containing the metal ion, the reducing agent, and the complexing agent with the second chemical liquid L2 containing the pH adjuster as the main component to thereby generate the plating liquid M. Furthermore, immediately after generating the plating liquid M, the controller 5 performs the plating processing on the substrate (wafer W) by using the generated plating liquid M. Therefore, the deterioration of the plating liquid M used in the electroless plating processing can be suppressed.

### Details of Plating Processing

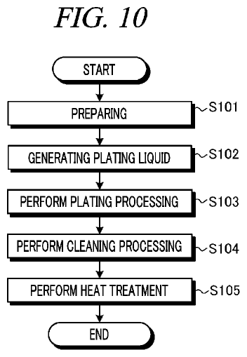

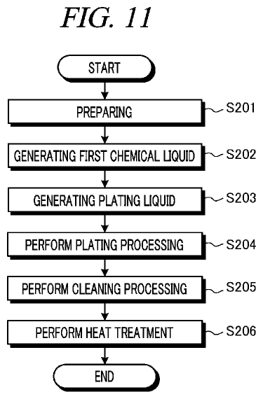

Now, referring to FIG. 10 and FIG. 11, details of the plating processing performed by the substrate processing system 1 according to the exemplary embodiment will be described. FIG. 10 is a flowchart illustrating a processing sequence of the plating processing according to the exemplary embodiment.

First, the controller 5 controls the substrate transfer devices 13 and 18 to carry the wafer W into the plating unit 16 from the carrier C, and holds the wafer W with the substrate holder 31, thus preparing the wafer W (process S101).

Then, the controller 5 controls the chemical liquid supply 32 to discharge the first chemical liquid L1 and the second chemical liquid L2 to the surface of the wafer W simultaneously to mix the first chemical liquid L1 and the second chemical liquid L2, thus generating the plating liquid M (process S102).

Immediately after the plating liquid M is generated, the controller 5 performs the electroless plating processing on the via 70 by using the plating liquid M (process S103). Further, the controller 5 controls the chemical liquid supply 32 to perform the preset cleaning processing on the wafer W after being subjected to the electroless plating processing (process S104).

Subsequently, the controller 5 controls the substrate transfer device 18 to carry the wafer W after being subjected to the electroless plating processing from the plating unit 16 into the heat treatment unit 17, and performs the predetermined heat treatment on the wafer W in the heat treatment unit 17 (process S105). Accordingly, the series of processings are ended.

FIG. 11 is a flowchart illustrating another processing sequence of the plating processing according to the exemplary embodiment. First, the controller 5 controls the substrate transfer devices 13 and 18 to carry the wafer W into the plating unit 16 from the carrier C, and holds the wafer W with the substrate holder 31, thus preparing the wafer W (process S201).

Next, the controller 5 controls the chemical liquid supply 32 to mix the third chemical liquid containing the metal ion and the fourth chemical liquid containing the reducing agent in the first supply 32a1 provided on the upstream side of the first nozzle 32d1 to generate the first chemical liquid L1 (process S202).

Thereafter, the controller 5 controls the chemical liquid supply 32 to simultaneously discharge the first chemical liquid L1 generated through the process S202 and the second chemical liquid L2 onto the surface of the wafer W, thus allowing the first chemical liquid L1 and the second chemical liquid L2 to be mixed with each other to generate the plating liquid M (process S203).

Then, immediately after the plating liquid M is generated, the controller 5 performs the electroless plating processing on the via 70 by using the plating liquid M (process S204). Further, the controller 5 controls the chemical liquid supply 32 to perform the preset cleaning processing on the wafer W after being subjected to the electroless plating processing (process S205).

Subsequently, the controller 5 controls the substrate transfer device 18 to transfer the wafer W after being subjected to the electroless plating processing from the plating unit 16 to the heat treatment unit 17, and then, the predetermined heat treatment is performed on the wafer W (process S206). Thus, the series of processings are ended.

A plating method according to the exemplary embodiment includes preparing (the processes S101 and S201), generating a plating liquid (the processes S102 and S203), and performing an electroless plating processing (the processes S103 and S204). In the preparing (the processes S101 and S201), the substrate (wafer W) is prepared. In the generating of the plating liquid (the processes S102 and S203), the plating liquid M is generated by mixing the first chemical liquid L1 containing the metal ion, the reducing agent and the complexing agent with the second chemical liquid L2 containing the pH adjuster as the main component. In the performing of the electroless plating processing (the processes S103 and S204), the substrate (wafer W) is subjected to the electroless plating processing by using the generated plating liquid M immediately after the generating of the plating liquid (the processes S102 and S203). Therefore, deterioration of the plating liquid M used for the electroless plating processing can be suppressed.

Further, in the plating method according to the exemplary embodiment, in the generating of the plating liquid (the processes S102 and S203), the first chemical liquid L1 is discharged to the substrate (wafer W) through the first nozzle 32d1. In addition, in the generating of the plating liquid (the processes S102 and S203), the second chemical liquid L2 is also discharged to the substrate (wafer W) through the second nozzle 32d2, so that the first chemical liquid L1 and the second chemical liquid L2 are mixed on the substrate (wafer W). As a result, even when the via 70 is miniaturized, the inside of the via 70 can be satisfactorily filled through the electroless plating processing.

In addition, in the plating method according to the exemplary embodiment, the generating of the plating liquid (the processes S102 and S203) is carried out by discharging the first chemical liquid L1 to the substrate (wafer W) on which the liquid film of the second chemical liquid L2 is formed. Therefore, even when the via 70 is miniaturized, the inside of the via 70 can be satisfactorily filled through the electroless plating processing.

Furthermore, in the plating method according to the exemplary embodiment, the generating of the plating liquid (the processes S102 and S203) is carried out by mixing the first chemical liquid L1 and the second chemical liquid L2 in the mixing nozzle 32d3. Therefore, even when the via 70 is miniaturized, the inside of the via 70 can be satisfactorily filled through the electroless plating processing.

Further, in the plating method according to the exemplary embodiment, the second chemical liquid L2 is configured to adjust the pH of the first chemical liquid L1 such that the pH of the first chemical liquid L1 is increased. Accordingly, the electroless plating processing can be performed in a simple way.

Moreover, in the plating method according to the exemplary embodiment, the second chemical liquid L2 is composed of the high-alkaline aqueous solution and the inevitable impurities. Therefore, the electroless plating processing can be performed in a simple manner.

Further, in the plating method according to the exemplary embodiment, the generating of the plating liquid (the processes S102 and S203) is performed after increasing the temperature of at least one of the first chemical liquid L1 and the second chemical liquid L2 to a temperature higher than the room temperature. Accordingly, even when the via 70 is miniaturized, the inside of the via 70 can be better filled through the electroless plating processing.

Furthermore, the plating method according to the exemplary embodiment further includes generating (the process S202), before the generating of the plating liquid, the first chemical liquid L1 by mixing the third chemical liquid containing the metal ion and the fourth chemical liquid containing the reducing agent. Accordingly, the activity of the plating liquid M generated by using the first chemical liquid L1 can be increased.

So far, the exemplary embodiment of the present disclosure has been described. However, the present disclosure is not limited to the above-described exemplary embodiment, and various changes and modifications may be made without departing from the spirit and scope of the present disclosure.

It should be noted that the above-described exemplary embodiment is illustrative in all aspects and is not anyway limiting. The above-described exemplary embodiment may be omitted, replaced and modified in various ways without departing from the scope and the spirit of claims.

### EXPLANATION OF CODES

1: Substrate processing system (example of plating apparatus)
5: Controller
16: Plating unit
31: Substrate holder
32: Chemical liquid supply
32d1: First nozzle
32d2: Second nozzle
32d3: Mixing nozzle
L1: First chemical liquid
L2: Second chemical liquid
M: Plating liquid
W: Wafer (example of substrate)

1. A plating method, comprising:
preparing a substrate;
generating a plating liquid by mixing a first chemical liquid containing a metal ion, a reducing agent and a complexing agent with a second chemical liquid containing a pH adjuster as a main component; and
performing an electroless plating processing on the substrate by using the generated plating liquid immediately after the generating of the plating liquid.

2. The plating method of claim 1,
wherein the generating of the plating liquid is performed by mixing the first chemical liquid and the second chemical liquid on the substrate while discharging the first chemical liquid through a first nozzle to the substrate and the second chemical liquid through a second nozzle to the substrate.

3. The plating method of claim 1,
wherein the generating of the plating liquid is performed by discharging the first chemical liquid to the substrate on which a liquid film of the second chemical liquid is formed.

4. The plating method of claim 1,
wherein the generating of the plating liquid is performed by mixing the first chemical liquid and the second chemical liquid in a mixing nozzle.

5. The plating method of claim 1,
wherein the second chemical liquid is configured to adjust a pH of the first chemical liquid such that the pH of the first chemical liquid is increased.

6. The plating method of claim 5,
wherein the second chemical liquid is composed of a high-alkaline aqueous solution and inevitable impurities.

7. The plating method of claim 1,
wherein the generating of the plating liquid is performed after increasing a temperature of at least one of the first chemical liquid and the second chemical liquid to a temperature higher than a room temperature.

8. The plating method of claim 1, further comprising:
generating, before the generating of the plating liquid, the first chemical liquid by mixing a third chemical liquid containing the metal ion and a fourth chemical liquid containing the reducing agent.

9. A plating apparatus, comprising:
a substrate holder configured to hold a substrate;
a chemical liquid supply configured to supply a chemical liquid to the substrate; and
a controller configured to control the substrate holder and the chemical liquid supply,
wherein the controller controls the substrate holder to hold the substrate,
the controller controls the chemical liquid supply to mix a first chemical liquid containing a metal ion, a reducing agent and a complexing agent with a second chemical liquid containing a pH adjuster as a main component to generate a plating liquid, and
the controller performs an electroless plating processing on the substrate by using the generated plating liquid immediately after the plating liquid is generated.
